(19) United States
(12) Patent Application Publication
(10) Pub. No.: US 2022/0119954 A1
(43) Pub. Date: Apr. 21, 2022

(54) SUBSTRATE PROCESSING TOOL CAPABLE OF MODULATING ONE OR MORE PLASMA TEMPORALLY AND/OR SPATIALLY

(71) Applicant: Lam Research Corporation, Fremont, CA (US)

(72) Inventors: Lee CHEN, Cedar Creek, TX (US); Yukinori SAKIYAMA, West Linn, OR (US); Karl Frederick LEESER, West Linn, OR (US)

(21) Appl. No.: 17/428,167

(22) PCT Filed: Jan. 28, 2020
(86) PCT No.: PCT/US2020/015375

§ 371 Date: Aug. 3, 2021

Related U.S. Application Data
(60) Provisional application No. 62/802,528, filed on Feb. 7, 2019.

(51) Int. Cl. C23C 16/517; C23C 16/505; H01J 37/32; C23C 16/52; C23C 16/26; H01J 37/34

(52) U.S. Cl. CPC C23C 16/517; C23C 16/505; H01J 37/32091; H01J 37/32422; H01J 37/3405; C23C 16/26; H01J 37/32146; H01J 37/32596; H01J 2237/3321; C23C 16/52

(57) ABSTRACT

A plasma tool in which the generation of two or more plasmas in a processing chamber used for processing a substrate is modulated either temporally, spatially, or both. The modulation of the two plasmas is used for the formation of Diamond Like Carbon (DLC) layers on substrates. One plasma is used for forming an amorphous carbon layer, while the second plasma is used for converting the amorphous carbon layer to a DLC by ion bombardment.

### CROSS REFERENCE TO RELATED APPLICATION

This application claims the benefit of priority of U.S. Application No. 62/802,528, filed Feb. 7, 2019, which is incorporated herein by reference for all purposes.

### BACKGROUND

The present invention relates to a substrate processing tool, and more particularly, to a plasma tool in which the generation of two or more plasmas in a processing chamber used for processing a substrate is modulated either temporally, spatially, or both. The present invention also related to the formation of Diamond Like Carbon (DLC) layers on substrates using either temporally and/or spatially modulated plasmas to form an amorphous carbon layer with one plasma and then converting the amorphous carbon layer to a DLC by ion bombardment with the other plasma.

Plasma Enhanced Chemical Vapor Deposition (PECVD) tools are used to produce high quality thin films onto various work pieces, such as semiconductor wafers, flat panel displays or photovoltaic devices. PECVD tools include a processing chamber. The type of film deposited on the work piece is dependent on the chemistry of the gasses that are introduced into the processing chamber. For instance, in the semiconductor industry, exemplary gasses include, but are not limited to, silane (SiH₄) or trichlorosilane (SiHCL₃) for the deposit of polysilicon, silane and oxygen (O₂), dichlorosilane (H₂SiCl₂), nitrous oxide (N₂O) and/or tetraethylorthos silicate (TEOS) for the deposit of silicon dioxide, tungsten hexaflouride (WF₆) for the deposit of tungsten, etc. In addition, reactant gas(es) such as water, alcohol, or a combination of both, are also often introduced into the chamber as well. When an RF potential is applied, a plasma is generated within the chamber. Within the plasma, energized electrons in the plasma ionize or “crack”, creating chemically reactive radicals. As these radicals react, they deposit and form a thin film on the semiconductor wafer. Various types of PECVD tools include Low Pressure (LPCVD), Ultra High Vacuum (UHVCVD), Atomic Layer Deposition (ALD), a Plasma-Enhanced Atomic Layer Deposition (PEALD), etc.

With the above mentioned tools, one or multiple wafers may be processed at a time. For a given processing cycle, one or more wafers are loaded into the processing chamber, gas(es) are introduced into the chamber and the plasma is generated and maintained until the deposited film is of desired thickness. Once the deposition is complete, the above process is repeated with a new batch of wafer(s). In general, such PECVD tools rely on only a single plasma during the deposition of a layer on a wafer or substrate surface.

Diamond-Like Carbon or “DLCs” are a class of amorphous carbon materials that exhibit diamond-like properties, including extreme hardness, wear resistance, and “slickness”. The most common DLC is tetrahedral amorphous carbon or “ta-C”, which is the hardest, most wear resistant and slickest among the class. Because of these properties, DLC materials are commonly used as protective coatings on a wide assortment of work pieces and can be applied to just about any material that is compatible with a vacuum environment.

Various plasma-based deposition techniques have been used to deposit ta-C onto substrates such as semiconductor wafers. Such techniques include Mass Selected Ion Beam (MSIB), Filtered Cathodic Vacuum Arc (FCVA), Pulsed Laser Ablation (PLA) and Electron Cyclotron Wave Resonance (ECWR). While each of these plasma-based techniques can be used for forming ta-C on a substrate in a laboratory setting, they are not practical for full scale fabrication of semiconductor wafers. For instance, the deposition rate for MSIB, FCVA and PLA is very low because each relies on a beam-based plasma source that has to scan the entire wafer. As a result, the deposition rate is too slow for semiconductor wafer fabrication on a large, industrial scale. ECWR, to some degree, overcomes the low deposition rate of the aforementioned other techniques. However, ECWR tools are extremely expensive and are too costly to be practically used for semiconductor wafer fabrication on a large, industrial scale. Conventional PECVD tools, which as noted above are commonly used for semiconductor wafer fabrication on an industrial scale, have previously been unable to generate mono-energetic ions, which is essential for the deposition of ta-C and other DLC like materials.

### SUMMARY

A plasma tool in which the generation of two or more plasmas in a processing chamber used for processing a substrate is modulated either temporally, spatially, or both. With time modulation, the two plasmas are alternatively activated either (a) during discrete non-overlapping pulses or (b) during non-overlapping portions of partially overlapping pulses. With spatial modulation, both plasmas are activated at the same time, either continuously or during overlapping portions of pulses.

In non-exclusive embodiments, the two plasmas are used the deposit and form a wide assortment of different materials onto the substrate. With such embodiments, the first plasma is used to deposit atoms that collect or rain down onto the surface of the substrate, while the second plasma is used to generate ions that bombard the surface of the substrate.

In another non-exclusive embodiment, the surface charges on the surface of the substrate is controlled by the two plasmas to maintain an equilibrium. By using an anode to control the potential of the second plasma with respect to the substrate, the energy of the ions that bombard the substrate can be controlled to maintain the equilibrium.

In yet another embodiment, the substrate is used as a stable ground path with respect to the second plasma.

In a specific, but non-exclusive embodiment, the modulation of the two plasmas is used for the formation of Diamond Like Carbon (DLC) layers on substrates. One plasma is used for forming an amorphous carbon layer, while the second plasma is used for converting the amorphous carbon layer to a DLC by ion bombardment. The DCL film consists of the group including hydrogenated amorphous carbon (a-C:H) and hydrogenated tetrahedral amorphous carbon (ta-C:H) and tetrahedral amorphous carbon or “ta-C.”

### BRIEF DESCRIPTION OF THE DRAWINGS

The present application, and the advantages thereof, may best be understood by reference to the following description taken in conjunction with the accompanying drawings in which:

FIG. 1A-1C are diagrams of a deposition tool capable of generating and modulating two or more plasmas in a processing chamber either temporally, spatially, or both in accordance with a non-exclusive embodiment of the invention.

FIGS. 1D and 1E illustrate the behavior of electrons generated originating in a first plasma source in accordance with a non-exclusive embodiment of the invention.

FIGS. 2A-2C illustrate timing diagrams for the modulation of two plasmas in a processing chamber in accordance with non-exclusive embodiments of the invention.

FIG. 3 is a diagram of another deposition tool capable of generating and modulating two or more plasmas in a processing chamber in accordance with another non-exclusive embodiment of the invention.

FIGS. 4A-4C are diagrams illustrating various embodiments for modulating two plasma either temporally and/or spatially generated by the deposition tool of FIG. 3 in accordance with non-exclusive embodiments of the invention.

FIG. 5 is a diagram illustrating a flow chart for fabricating a semiconductor wafer using a Diamond Like Carbon mask formed using a deposition tool in accordance with the present invention.

In the drawings, like reference numerals are sometimes used to designate like structural elements. It should also be appreciated that the depictions in the figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are set forth in order to provide a thorough understanding of the present disclosure. It will be apparent, however, to one skilled in the art, that the present discloser may be practiced without some or all of these specific details. In other instances, well known process steps and/or structures have not been described in detail in order to not unnecessarily obscure the present disclosure.

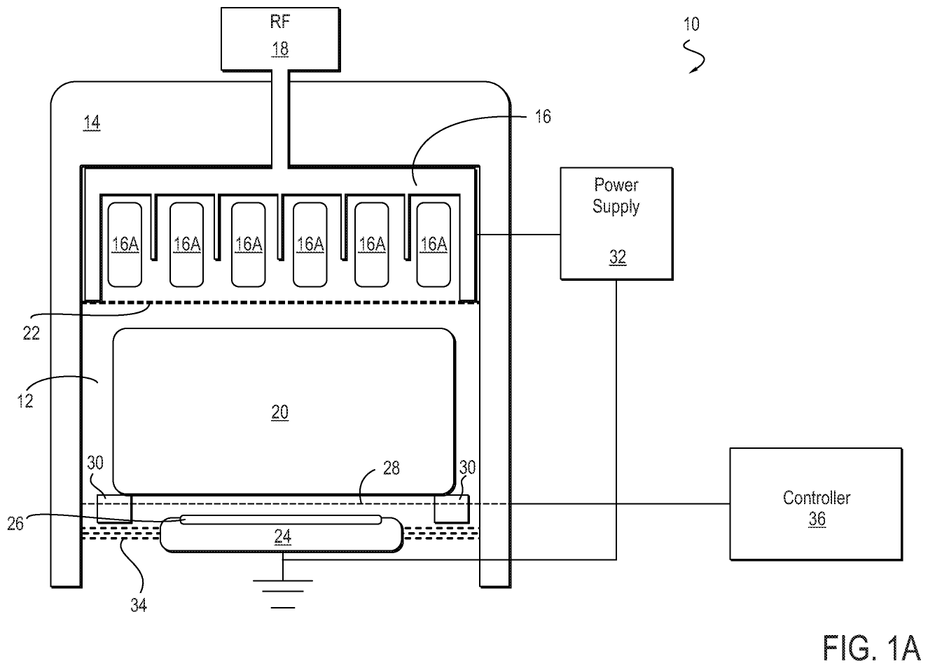

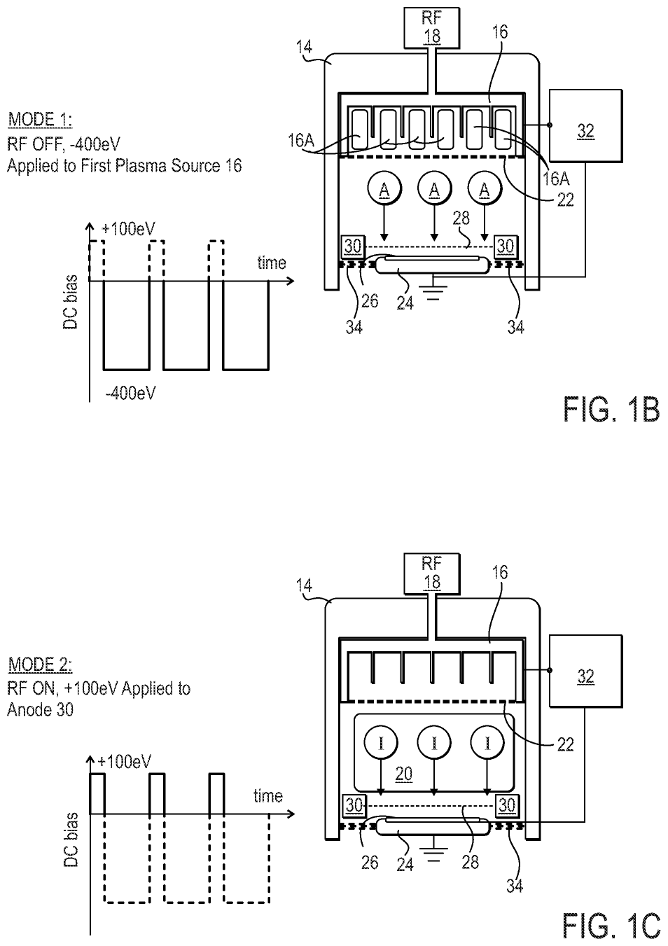

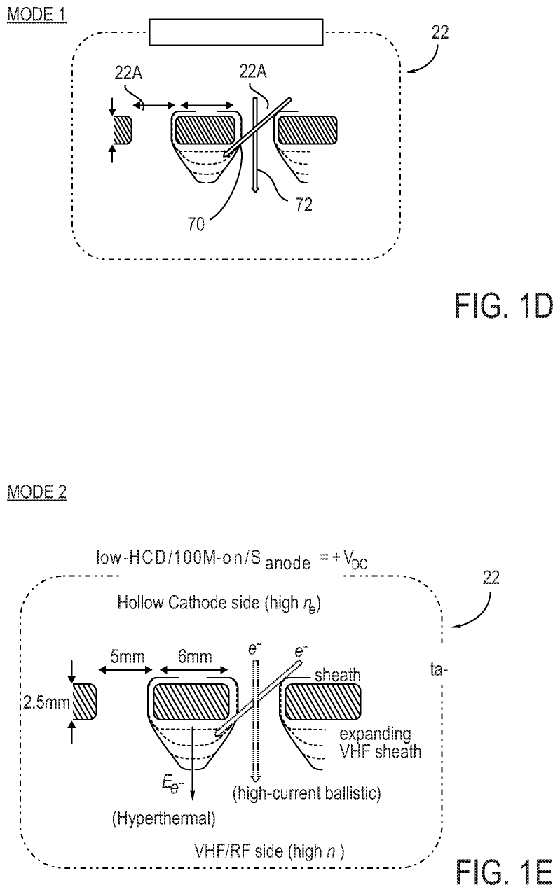

Referring to FIG. 1A, a diagram of a deposition tool 10 capable of generating and modulating two or more plasmas in a processing chamber 12 is illustrated. As described in detail below, the deposition tool 10 has the ability to generate two plasmas that may be modulated either temporally, spatially, or both when processing substrates.

The deposition tool 10 includes the processing chamber 12 defined by chamber walls 14, a first plasma source 16 for selectively generating a first plasma 16A, an RF source 18 for selectively activating a second plasma 20 within the processing chamber 12, a mesh 22 provided adjacent to the first plasma source 16 and above the second plasma 20 when activated, a substrate holder 24 for holding a substrate 26 within the processing chamber 12, a neutralizing barrier 28 provided between the second plasma 20 and the substrate 26, an anode 30, a bi-directional power supply 32, a plasma exhaust 34 and a controller 36.

The walls 14 defining the processing chamber are made at least partially from an electrically non-conductive material. In various non-exclusive embodiments, the non-conductive material can be ceramic (e.g., (Al₂O₃), quartz, sapphire, or other dielectric material(s). The exact material used for the sidewalls 14 of a given deposition tool 10 depends on a number of factors, including compatibility with the chemistry or chemistries used within the processing chamber 12. It is also desirable to create or maintain an “air gap” on the atmosphere side of the processing chamber 12, between the dielectric walls 14 and a Radio Frequency ground shield that is generated around the tool 10. Such “air gap” provides “low capacitance” around the processing chamber 12. As a result, a VHF ground-return looped is provided through the substrate 26 and not through the walls 14 of the processing chamber 12. Since for just about any deposition tool 10 used for commercial production, the substrate 26 is the most reliable repeatable surface, forcing the VHF ground return through the substrate 26 provides predictability and all but eliminates variations caused by varying degrees of incidental deposition material forming on the walls 14 of the processing chamber 12.

The first plasma source 16 is configured to generate a first plasma 16A of a material to be deposited on the substrate 26. In one non-exclusive embodiment, the first plasma source 16 is a Hollow Cathode Discharge (HCD) device made of at least partially the material to be deposited onto the substrate 26. For instance, if the material to be deposited is carbon atoms, then the HCD device can be made of a carbon-bearing material such as graphite. In another non-exclusive embodiment, the first plasma source 16 is a HCD device made from a material that is not deposited on the substrate 26, but is arranged to contain or receive the material that is to be deposited. For instance, the HCD device can be made of aluminum or doped silicon, but is arranged to contain or otherwise receive the material to be deposited (e.g., graphite rods if carbon is to be deposited). In yet another non-exclusive embodiment, the first plasma source 16 is a magnetron arranged to sputter off atoms or other particles of the material to be deposited on the substrate 26. Again, if the material to be deposited onto the substrate 26 is carbon atoms, then a magnetron implementation of the first plasma source 16 would be arranged to sputter off carbon atoms. In the particular embodiment shown, the first plasma source 16 defines a plurality of cells or chambers. Within each cell or chamber, regions of the first plasma 16A are generated.

The RF source 18, which is connected to the first plasma source 16, is used to selectively activate the second plasma 20 within the processing chamber. In various embodiments, the RF source is 100 MHz, 13 MHz, 27 MHz, or any other RF frequency suitable for generating the second plasma 20 within the processing chamber 12. Such suitable frequencies may fall within what is generally considered to be the low, medium or high radio frequency ranges, and may range from 400 kHz to 5 GHz.

The second plasma 20 is generated within the processing chamber 12 when the RF source 18 is activated. In a non-exclusive embodiment, the second plasma is a Capacitive Coupled Plasma (CCP). In other embodiments, the plasma can be also be an inductively coupled plasma as well.

The mesh 22 is provided under the first plasma source 16 and above the second plasma 20. The mesh 22 includes a plurality of holes facing the substrate 26. With this arrangement, the mesh 22 allows atoms or other particles generated by the first plasma 16A to pass through the holes of the mesh. As these atoms or particles exit the mesh 22, they “rain” down and deposit onto the substrate 26 at a relatively low energy. On the other hand, as described in more detail below, if the second plasma 20 activated and energized, then a certain percentage of the atoms or particles may ionize and bombard the substrate 26.

The substrate holder 24 is provided within the processing chamber 12. The purpose of the substrate holder 24 is to hold or clamp the substrate 26 in place during processing within the chamber 12. In various embodiments, the substrate holder 24 may hold or clamp the substrate 26 by way of an electrostatic chucking force, mechanical chucking, or any combination thereof.

For instance, if the substrate holder 24 is an Electrostatic Clamp (ESC), then the substrate 26 is only capacitively-grounded, not necessarily DC-grounded. Since the surface of an ESC chuck contacting the substrate 26 is typically an insulator or a semiconductor, the substrate 26 is generally considered as electrically “floating”, meaning the substrate is capacitively grounded (or actively biased) with respect to the first and second plasmas 16A, 20, but is not at DC-ground.

In embodiments where an active bias is used, the bias may widely range. By way of example, the active bias may range from negative 1 kV to positive 1 kV. It should be noted that active bias voltages may range in magnitude to be larger or smaller than positive/negative 1 KV.

In yet another embodiment, the substrate holder 24 also has the ability to control the temperature of the substrate 26 during processing. For instance, during substrate deposition, the temperatures within the chamber 12 are elevated and may range from room or ambient temperature to approximately 300° C. In such an environment, the substrate holder 24, typically operates to maintain the substrate 26 at a lower temperature than 300° C., such as less than 100° C. or 200° C. It should be understood that the above-listed temperatures are merely exemplary and should not be construed as limiting in any regard. The operating range within the processing chamber 12 may be either higher or lower than room or ambient temperature to approximately 300° C., and accordingly, the substrate 26 may be maintained at higher or lower temperatures than those listed above. As such, the substrate holder 26 in non-exclusive embodiments may alternatively have to the ability to control the temperature of the substrate anywhere from 20° C. or less to 300° C. or more.

The neutralizing barrier 28, which also includes a plurality of holes facing the substrate 26, is provided between the second plasma 20 and the substrate 26. The neutralizing barrier 28 performs at least two functions. One function is that it provides a physical barrier between the second plasma 20 and the substrate 26, substantially preventing the second plasma 20 from contacting the substrate 26. The neutralizing barrier 28 also acts, in certain non-exclusive embodiments, to help reduce the energy flux on the substrate 26. In such embodiments, the neutralizing barrier 28 is made from a material that is capable of supplying charged particles. As charged ions or other particles of one polarity pass though the holes of the neutralizing barrier 28, they tend to attract charged particles of the opposing polarity supplied by neutralizing barrier 28. The charge of the ions or particles, as they pass through the neutralizing barrier 28, become neutralized just prior to bombarding the substrate 26. The energy flux on the surface of the substrate 26 can therefore be at least partially controlled or otherwise reduced by the neutralizing barrier 28. For example, if the particles generated by the plasma are positively charged ions, then the neutralizing barrier 28 is preferably made from a material capable of bearing electrons, such as graphite. When the positively charged ions are thus neutralized by the electrons prior to bombarding the substrate 26.

The anode 30, which in a non-exclusive embodiment is ring-shaped, is provided adjacent to or around the substrate 26 and under the location of the second plasma 20 in the processing chamber 12. The function of the anode 30 is to selectively apply a positive voltage to the second plasma 20 so that there is a voltage differential between the second plasma 20 and the substrate 26. By controlling the voltage of the second plasma 20, the energy level of atoms or particles that are ionized may be controlled with respect to the substrate 26. In various embodiments, the voltage applied to the second plasma 20 by the anode 30 may widely range, depending on the process requirements. For instance, the voltage applied to the anode 30 can be adjusted anywhere from approximately +30 eV to approximately +1 kV. Again, this range is merely exemplary and actual voltages applied to the anode 30 may be larger or smaller in magnitude. When the anode 30 is not turned on, it is at or near ground.

The voltage of the second plasma 20, sometimes referred to as the “artificial plasma potential” or “boundary-driven plasma potential,” is typically a little larger than that of the voltage applied by the anode 3, provided the surface area of the anode 30 is sufficiently large. For example, when area of the anode 30 is sufficient, and +100V is applied by the anode 30, the resulting artificial plasma potential is driven up to a potential larger than +100V, such as approximately +110V. In another words, the natural potential or the artificial potential of the plasma 20 is higher than the highest voltage of any surface of the anode 30 in contact with the plasma provided, the said surface, is “sufficiently large”.

Although the anode 30 depicted in the figures is ring-shaped, it should be understood that the anode 30 can assume a wide variety of different shapes. Regardless of the shape used, the surface area of the anode is preferably “sufficiently large” with respect to the substrate 26. While the definition of sufficiently large may vary from circumstance to circumstance, as a general rule, the anode 30 should have a surface area that is approximately the same or larger than that of the substrate 26. That said, the surface area of the anode 30 being the same or larger than the substrate 26 is not an absolute requirement. On the contrary, the surface area of the anode 30 can be smaller than the substrate 26. The relative surface areas of the substrate 26 and the anode 30 is at least partially dependent on the extent to which the “artificial potential” or “boundary-driven potential” of the plasma 20 is wanted or desired.

The power supply 32 is provided to selectively provide power to the first plasma source 16. In a non exclusive embodiment, the power supply is a pulsed, DC, bi-directional (+/−) power supply capable of supplying voltages of up to +/−700 eV or more to the first plasma source 16. In a non-exclusive embodiment, the power supply 32 is a Matsusada AMPS-0.6B2000 power supply. It should be understood that other power supplies can also be used.

The plasma exhaust 34 is provided at or near the bottom of the chamber 12 and is provided to exhaust or otherwise remove plasma and other gases and/or materials from the processing chamber 12. In a non-exclusive embodiment, the plasma exhaust 34 relies on a vacuum to pull the plasma, gases and/or other materials from the chamber 12.

The controller 36 is employed to control operation and process conditions of the tool 10 prior to, during, and post deposition. In particular, the controller 36 is provided to manage and control the overall operation of the deposition tool 10 by operating the various components, including but not limited to the first plasma source 16, the RF source 18, the substrate holder 24 including any bias applied to the substrate 26 and/or controlling the temperature of the substrate 26, the anode 30 for controlling the voltage of the second plasma, the power supply 32 coupled to the first plasma source 16, and the plasma exhaust 34.

The controller 36 typically includes one or more non-transient computer readable medium devices for storing system control software or code and one or more processors for executing the code. The term “non-transient computer readable medium” is used generally to refer to media such as main memory, secondary memory, removable storage, and storage devices, such as hard disks, flash memory, disk drive memory, CD-ROM and other forms of persistent memory, but not transitory subject matter, such as carrier waves or signals. The processor may include a CPU or computer, multiple CPUs or computers, analog and/or digital input/output connections, motor controller boards, etc.

In certain embodiments, the controller 36, running or executing the system software or code, controls all or at least most of the activities of the tool 10, including such activities as controlling the timing of the processing operations, frequency and power of operations of the RF generator 18, pressure within the processing chamber 12, flow rates, concentrations and temperatures of any gas(es) into the process chamber 12 and their relative mixing, temperature of a substrate 26 supported by the substrate holder 24, etc.

The controller 36 may also include a user interface (not shown). The user interface may include a display screen, graphical software displays of indicative of operating parameters and/or process conditions of the tool 10, and user input devices such as pointing devices, keyboards, touch screens, microphones, etc., that allow a human operator to interface with the tool 10.

Information transferred between the controller 36 and the various above-listed components of the tool 10 may be in the form of signals such as electronic, electromagnetic, optical, or other signals capable of being transmitted and/or received via any communication link that carries signals and may be implemented using wire or cable, fiber optics, a phone line, a cellular phone link, a radio frequency link, and/or other communication channels.

### Plasma Modulation

The tool 10, under the control of the controller 36, is capable of modulating the first plasma 16A and the second plasma 20 temporally, spatially, or both temporally and spatially.

Referring to FIGS. 1B and 1C, diagrams illustrating the temporal modulation of the first plasma 16A and the second plasma 20 are illustrated. The two plasmas 16A and 20 are temporally modulated by pulsing one of the two plasmas on, while the other plasma is pulsed off. For the discussion below, a first mode is defined as when the first plasma 16A is activated while the second plasma 20 is deactivated. A second mode is defined as the complement of the first mode, meaning the second plasma 20 is activated, while the first plasma 16A is deactivated.

In the first mode, as illustrated in FIG. 1B, the controller 36 operates to (a) direct the power supply 32 to apply a negative voltage to the first plasma source 16, (b) turn off the RF source 18, and (c) ground the anode 30. As a result, the first plasma 16A is activated within the cells of the of the first plasma source 16, while the second plasma 20 is deactivated. Under this first set of conditions, particles or atoms “A”, generated by the first plasma source 16, fall through the holes of the mesh 22 and “rain” down and deposit on the substrate 26.

In the second mode, as illustrated in FIG. 1C, the controller 36 operates to (a) direct the power supply 32 to apply no voltage to the first plasma source 16, (b) turns on the RF source 18 and (c) activates the anode 30. As a result, the first plasma 16A is deactivated, while the second plasma 20 is activated and maintained at the positive voltage of the anode 30 with respect to the substrate 26. Under this second set of conditions, a certain percentage of the particles or atoms previously generated by the first plasma 16A and that pass through the mesh 22 are ionized “I” by the plasma and have an energy level the same as the voltage of the anode 30. As a result, the positively charged ions accelerate and bombard the substrate 26, which is maintained at ground or a bias voltage.

Time modulation thus involves alternating the effusive (thermal) flux of atoms A onto the wafer with energetic ions (100 eV C+) onto the substrate 26, in time. In various embodiments, the two plasmas 16A and 20 can be temporally modulated in one of the following ways (a) alternating the activation of the first plasma 16A and the second plasma 20 in discrete, non-overlapping, pulses or (b) alternating the activation of the first plasma 16A and the second plasma 20 in partially overlapping pulses. To the extent the pulses do not overlap, the two plasmas are being modulated temporally.

Spatial modulation occurs when the two plasmas 16A and 20 are activated at the same time. With both plasmas activated, the effusive (thermal) flux of atoms A onto the wafer with energetic ions (100 eV C+) onto the substrate occurs at the same time. In other words, certain discrete portions of the surface of the substrate 26 receive the thermal influx of atoms, while simultaneously certain discrete portions of the surface of the substrate are being bombarded with ions. Thus, to the extent the two plasmas 16A, 20 are both activated at the same time, during either partially overlapping pulses or continuously, spatial modulation is occurring.

FIGS. 1D and 1E illustrate the behavior of electrons originating in the first plasma source 16 in the first mode and the second mode respectively.

Within the hallow cathode of the first plasma source 16, free electrons are traveling in a multitude of directions. The electrons traveling substantially horizontally, as signified by the arrow 70, will strike surfaces within the first plasma source 16. As a result, these electrons will not pass through the holes 22A of the mesh 22. On the other hand, the electrons traveling in a direction mostly perpendicular to the holes 22A, as signified by the vertical arrow 72, will pass through the mesh 22 and travel toward the substrate 26. The behavior of these “escaping” electrodes differs depending on the mode of operation.

In the first mode, the second plasma 20 is not activated. Since the substrate 26 is at ground or is biased, the electrons will travel toward the substrate. On the other hand in the second mode, the positively charged plasma 20 is activated and its sheath expands at least partially into the region occupied by the first plasma source 16. As a result, the escaped electrons go “ballistic”, meaning the positive voltage of the plasma 20 causes the electrons to accelerate toward the substrate 26 at a higher spIED than otherwise would occur without the influence of the sheath.

### Modulation Examples

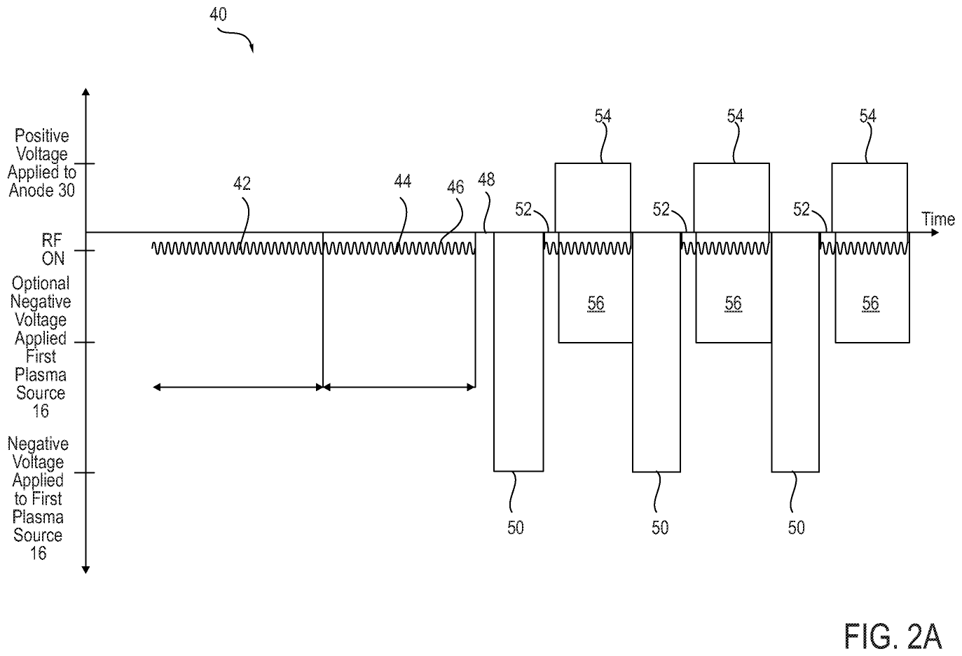

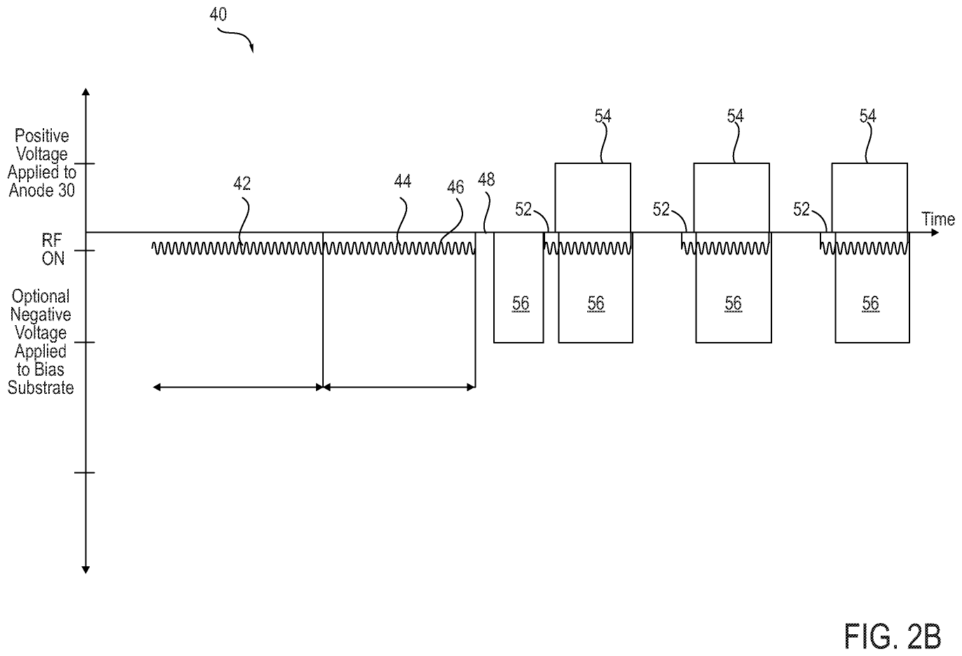

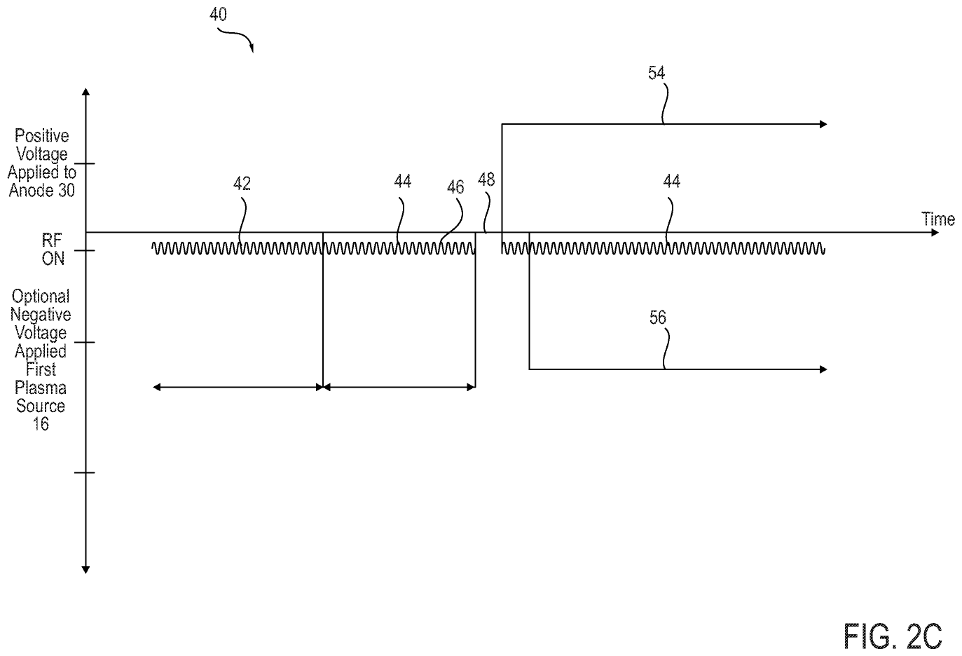

Referring to FIG. 2A, a timing diagram 40 illustrating the temporal modulation of the two plasmas 16A, 20 in discrete pulses over time is illustrated.

In this diagram, a number of voltages are plotted on the vertical axis, including from top to bottom (a) a positive voltage applied to the anode 30 for controlling the voltage of the second plasma 20, (b) a negative bias potential that is optionally be applied to the first plasma source 16 during mode two operation and (c) a negative voltage applied to the first plasma source 16 by the power supply 32 during mode one operation. Time is plotted along the horizontal axis. As described below, a number of timed, non-overlapping, pulses for activating the two plasmas 16A and 20 occur in a time sequence along the horizontal axis.

Initially, in the time period designated by reference number 42, the second plasma 20 is turned on and “warmed up” by activating the RF source 18. The warm up period allows the RF source 18 (designated by the oscillating wave 44) and the resulting second plasma 20 to stabilize.

Next, in the time pulse 46, the first plasma source 16 is activated by switching on the power source 32. As a result, the first plasma source 16A is generated and given time to stabilize. During this period, both the first plasma 16A and the second plasma 20 are activated for a sufficient time to stabilize.

During the time period 48, both the first plasma 16A and the second plasma 20 are switched off for a brief period of time (e.g., 15 microseconds) after stabilization. The first plasma 16A is deactivated by switching off the power supply 32, while the RF source 18 is turned off to deactivate the second plasma 20. The modulation sequence is now ready to begin.

Starting at time pulse 50, the first plasma 16A is pulsed on (mode 1) by power supply 32 for the duration of the pulse, while the RF source 18 remains off. With the first plasma 16A activated, homogenized, thermal particle or atoms of low energy are generated. Some of these particles or atoms pass though the mesh 22 and enter the main cavity of the processing chamber 12, falling or raining down onto the substrate 26. The power supply 32 deactivates the first plasma 16A when pulse 50 expires.

At time 52, the RF power source 18 is turned back on and is given time to stabilize (e.g., 15 microseconds). The time period 52 should be sufficiently long to allow the second plasma 20 to stabilize and become capacitively coupled. At 100 MHz, stabilization and coupling is relatively fast, typically occurring in the range of 1 to 10 microseconds.

Starting with time pulse 54, the second plasma 20 is activated (mode 2) in response to the RF power source 18 When activated, a percentage of the particles or atoms that passed through the mesh 22 from the first plasma source 16A become ionized in the second plasma 20 and have a high energy that is measured by the voltage difference between (a) the voltage of the plasma 20 as determined by the anode 30 and (b) the voltage of the substrate 26, which is either at ground or at a bias voltage. When the pulse 54 expires, the RF source is shut off and the plasma 20 is deactivated.

The pulse 56 largely overlaps with the pulse 54. During pulse 56, the power supply 32 provides a negative voltage to the first plasma source 16. The negative voltage applied to the first plasma source 16 during this pulse (mode 2) is typically less in magnitude that pulse 50 (mode 1). During this pulse 56, the first plasma source 16 generates atoms or particles, albeit at a lower rate than in pulse 50. In addition, “ballistic” electrons are generated as well. A certain percentage of the atoms generated during this pulse 56 are ionization within the plasma 20. As these ions bombard the substrate 26, positive surfaces charges accumulate. The ballistic electrons, however, act to counter the accumulation of the positive charges, helping neutralize the surface charges on the substrate 26.

The sequence of pulse 50, time period 52 and pulses 54, 56 may be repeated indefinitely. With each cycle, (a) particles or atoms are generated in the first plasma 16A and deposit on the substrate 26 and (b) the second plasma ionized the atoms or particles, resulting in bombardment of the substrate.

The duration of the pulses 50, 54, 56 and the time period 52 between the pulses, may widely vary. In one specific, but non-exclusive embodiment, the pulses 50 range from 70 to 90 microseconds, the time period 52 is approximately (15 microseconds), and the pulses 54, 56 range from 90 to 95 microseconds. It should be understood that these time values are exemplary and should not be construed as limiting. On the contrary, the duration of 50, 52, 54 and 56 may each widely vary and depend on a number of factors, such as for a given deposition layer process, the film or films being deposited, a desirable duration for depositing atoms or particles on the substrate 26, the desirable duration for bombarding the substrate 26, the time period required for the two plasma sources 16A and 20 to stabilize, and/or the time for the second plasma source to reach the artificial potential or boundary-driven potential. These are just a few of the factors that may be used in determining the time values for the various pulses and the time periods between the pulses. Accordingly, in alternative embodiments, the pulses 50 may widely range to have time-widths that are longer or shorter in duration than in the examples provided herein.

In the embodiment provided in FIG. 2A, the pulses 50 and 54 are discrete and non-overlapping. The pulses 50 and 54 can also be arranged to overlap or be continuous.

Referring to FIG. 2B, an embodiment of overlapping pulses for activating the first plasma 16A and the second plasma 20 is illustrated. As evident in this timing diagram, the power supply 32 and the RF source 18 are repeatedly pulse on at approximately the same time. As a result, the pulses 50 and 56 substantially overlap.

Referring to FIG. 2C, an embodiment of continuous pulses 50 and 54 is illustrated. As evident in this timing diagram, the power supply 32 and the RF source 18 are pulsed on continuously after stabilization of the two plasmas 16A, 20. As a result, the pulses 50 and 56 when the first plasma 16A and the second plasma 20 are activated are continuously.

The discrete pulsing of the first plasma 16A with respect to the second plasma 20, as illustrated in FIG. 2A, results in a temporal modulation of the two plasmas with respect to one another. As previously noted, this results in the alternating the effusive (thermal) flux of atoms A onto the wafer with energetic ions (100 eV C+) onto the substrate 26, in time.

When both the first plasma 16A and the second plasma 20 are activated at the same time, either with overlapping pulses or continuously, the two plasmas are spatially modulated. In other words, certain discrete portions of the surface of the substrate 26 receive the thermal influx of atoms, while simultaneously certain discrete portions of the surface of the substrate are being bombarded with ions.

The above-described process thus provides the ability of selectively and controllably (a) select a species to be deposited and (2) regulate ion distribution within the processing chamber 12 of the deposition tool 10 in ways previously not possible.

### Formation of Diamond-Like (DCL) Like Layers

As previously noted, Diamond-Like Carbon or “DLCs” are a class of amorphous carbon materials that exhibit diamond like properties, including extreme hardness, wear resistance and “slickness”. Common DLC materials include hydrogenated amorphous carbon (a-C:H) and hydrogenated tetrahedral amorphous carbon (ta-C:H) and tetrahedral amorphous carbon or “ta-C”, which is the hardest, most wear resistant and slickest among the group.

The use DLC materials is desirable in many applications, such as for forming hard masks in semiconductor wafer fabrication. A hard mask is preferably used in the semiconductor industry as an etch mask instead of other “soft” organic materials, such as polymer resist. With common etchant gases used in plasma etching, such as fluorine, chlorine, etc., “soft” polymer masks are susceptible to degradation. As a result, the etched features on the semiconductor wafer are less precise. An amorphous carbon DLC mask, such as ta-C, on the other hand, is significantly more stable, with a very low, but predictable, etch rate. Ta-C hard masks, therefore have significantly less degradation when exposed to fluorine and/or chlorine etching chemistries compared to a polymer resin, resulting more precise etches, finer geometries, and fewer processing defects.

The above-described plasma modulation technique can be implemented with existing PECVD tools with little to no modifications. As a result, such PECVD tools can be used to deposit and form DLC layers used for hard masks on semiconductor wafers, with a throughput sufficient to support large scale, industrial, production.

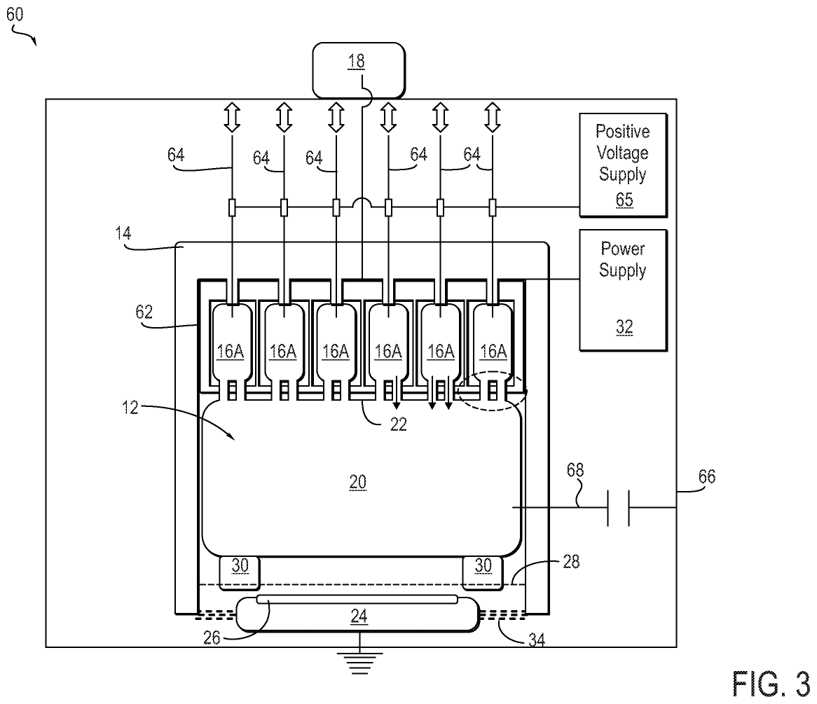

Referring to FIG. 3, a diagram of a deposition tool 60 capable of depositing a DLC layer, such as to-C, is illustrated. The deposition tool 60 includes a processing chamber 12 defined by chamber walls 14, a first plasma source 62 for generating a first plasma 16A, an RF source 18 for selectively activating a second plasma 20 within the processing chamber 12, a mesh 22 provided below the first plasma source 16 and above the second plasma 20, a substrate holder 24 for holding a substrate 26 within the processing chamber 12, a neutralizing barrier 28 provided between the second plasma 20 and the substrate 26, an anode 30, a power supply 32, a plasma exhaust 34 and a controller 36 (not illustrated). The elements listed above having reference numbers in common with those previously mentioned are essentially the same and are not described again herein for the sake of brevity. In addition, the deposition tool 60 includes a number of additional elements and features previously not described.

The first plasma source 62 is a hollow cathode for generating carbon atoms. In a non-exclusive embodiment, the hollow cathode is made of a non-carbon bearing material, such as aluminum or doped silicon. To generate the nIEDed carbon atoms, the hollow cathode is configured to receive a carbon bearing material. In the particular embodiment shown, this is accomplished by introducing graphite rods 64 into the individual cells defined within the hallow cathode of the first plasma source 62.

When the first plasma 16A of carbon is to be generated, the following sequence is initiated:

(a) The cells of the first plasma source are filled with an ignition gas, such as helium or argon;

(b) The power supply 32 applies a negative voltage (e.g., −400 eV) to the first plasma source 62. As a result, a plasma of the ignition gas is generated in the individual cells; and

(c) The graphite rods 64, biased with a DC voltage provided by voltage supply 65, is inserted into the plasma within the individual cells. In different embodiments, the graphite rods 64 can be either negative biased or positive biased. In the negative bias operation, the graphite is sputtered by ions generated within the first plasma source 16 or HCD. In the positive biased operation, a voltage in the range of +100 to +500 volts is applied to the graphite rods. Within this range, electrons within the HCD bombard the graphite rods 64. The resulting high electron current causes the rods 64 to heat up to the temperature where carbon sublimation starts (e.g., >2000° C.; graphite sublime at >4000° C. in atmosphere and the value is much reduced in vacuum to something like 2000° C. or lower). Once a steady state of the generation of carbon atoms is achieved by sublimation, the source of the ignition gas weaned down and eventually shut off completely. The net result is a substantially pure plasma of homogenized, thermal, carbon atoms. It should be noted that graphite rods 64 are just one type of carbon source that can be used.

The resulting carbon atoms then pass through the mesh 22 and into the region occupied by the second plasma 20. In a non-exclusive embodiment, the mesh 22 is a Bebye exit plate with a transparency defined by holes having a diameter that is significantly larger than the Debye length of the first plasma 16A. With this arrangement, the first plasma 16A defines a source of highly homogenized carbon atoms. As these atoms exit the super-Debye plate, a certain degree of the carbon atoms are thermalized. A highly thermalized C atom “soup” exiting the mesh allows a more homogeneous deposition of an amorphous carbon layer onto the surface of the substrate 26, waiting to be converted to ta-C through the sub-plantation of the energetic carbon ions.

In a non-exclusive embodiment, the second plasma 20 is a high frequency (e.g., 100 MHz) capacitively coupled plasma. At higher frequencies such as those around 100 MHZ, the presence of the second plasma 20 aids in the ignition of the first plasma 16A within the first plasma source 16, either following the 100 Mhz-ccp's afterglow or, few microseconds after 100 Mhz-ccp is stabilized.

With the arrangement of the tool 60 as illustrated in FIG. 3, the substrate 26 effectively provides a highly stable and reliable RF ground return path with respect to the RF source 18. The first plasma source 62 (or HCD) is coupled to the RF source 18 at 100 MHz. The portions of the HCD inside the processing chamber 12 are maintained at vacuum, while the exterior portions are at atmosphere. Since the walls 14 of the processing chamber 12 are made of a dielectric material, the 100 MHz RF radiates through, but is blocked by the ground shield 66. A stray capacitance, illustrated as 68, is the capacitance of the processing chamber 12 to “real ground” as defined by the ground shield 66. Since atmosphere (e.g., air) has low permittivity, the capacitance 68 is typically very small. As a result, the HCD at the 100 MHz RF sees a very high impedance with respect to the ground shield 66. The substrate 26, on the other hand, is either at direct-current ground or at a reactive ground, depending on the type of chuck used. Either way, the substrate 26 and substrate holder 24 provides a stable ground return path. The use of the substrate 26 as a VHF ground return thus provides a highly reliable and repeatable return path.

The modulation of the first plasma 16A and the second plasma 20 is used to generate a DLC layer, such as to-C.

In a first mode, a carbon plasma is generated by the first plasma source 62 in the manner described above. As a result, homogenized, low or thermal energy, amorphous, carbon atoms are generated. As these amorphous carbon atoms pass through the mesh 22, they rain down and deposit on the substrate 26, creating an amorphous carbon layer, having mostly sp2 bonds.

In a second mode, the second plasma 20 is activated by switching the RF power source 18 on. The RF power source causes a certain percentage of the carbon atoms in the processing chamber 12 to become ionized in a very fast period of time (e.g., approximately 10 microseconds). As a result, a plasma sheath containing the carbon ions is created above the substrate 26.

The anode 30 applies a positive voltage to the plasma 20, which positively charges the carbon ions with respect to the substrate 26, which is maintained at ground or is optionally biased. As a result, these mono-energetic carbon ions accelerate toward and bombard the substrate 26.

The anode 30 provides a unique role in controlling the potential or voltage of the plasma 20 with respect to the surface of the substrate 26. For instance, the anode 30 can be used to boost the natural plasma potential to the boundary driven plasma potential in a very short period of time, ranging from 1 to 10 microseconds and typically within 1 or 2 microseconds. When the boundary driven plasma potential is established, a strong plasma sheath is created and the carbon ions have more energy than would otherwise occur at the natural plasma potential. As the positive carbon ions bombard the surface of the substrate 26, its floating surface voltage may drift upward, meaning the boundary driven plasma potential drops. But by increasing the potential of the anode 30, the boundary driven plasma potential can be increased. In addition, the first plasma 16A can be weakly turned on, resulting in the injection of electrons hitting the surface of the substrate. As a result, the charge on the substrate 26 can be further controlled, which in turn, means the duration of the ion bombardment can be extended. This approach is different than normal where the potential of the substrate 26 is reduced to increase the potential with a plasma.

The bombarding of the amorphous carbon layer by mono-energetic carbon ions results in the spontaneous formation of sp3 bonds by a process known as sub-plantation. The sp3 bonds, in turn, cause a transformation of the amorphous carbon layer to a diamond-like ta-C layer. The ta-C layer on substrate 26 is thus realized by (a) forming the amorphous carbon layer on the substrate 26 from a pure carbons source and (b) controlling the bombardment energy of the carbon ions.

The first plasma for generating carbon atoms and the second plasma for ionizing the carbon atoms can be modulated temporally, spatially or both. This is accomplished by implementing the two above-described modes either (a) at discrete time intervals. (b) at overlapping time intervals or (c) both continuously. In particular:

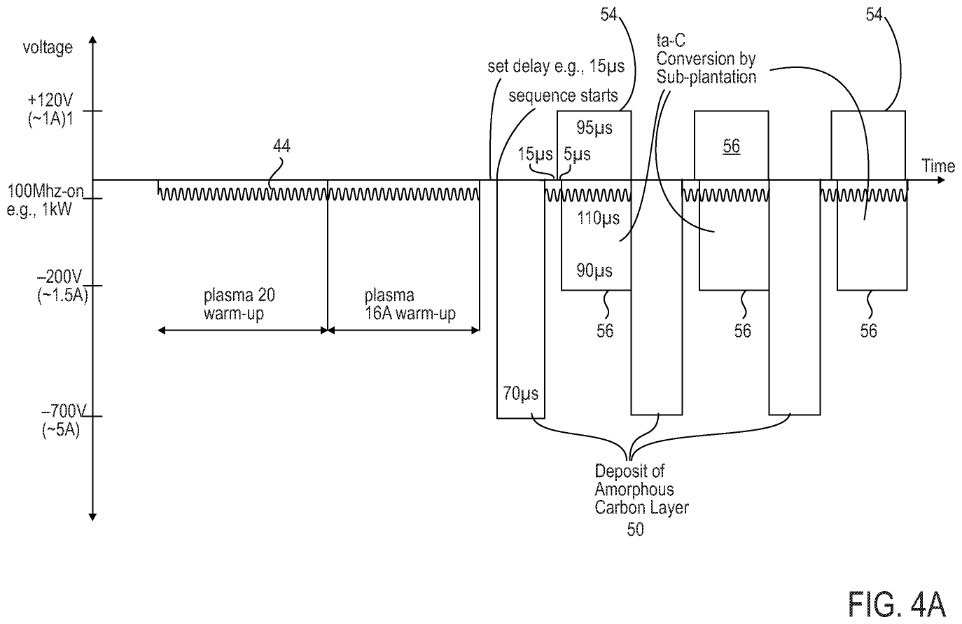

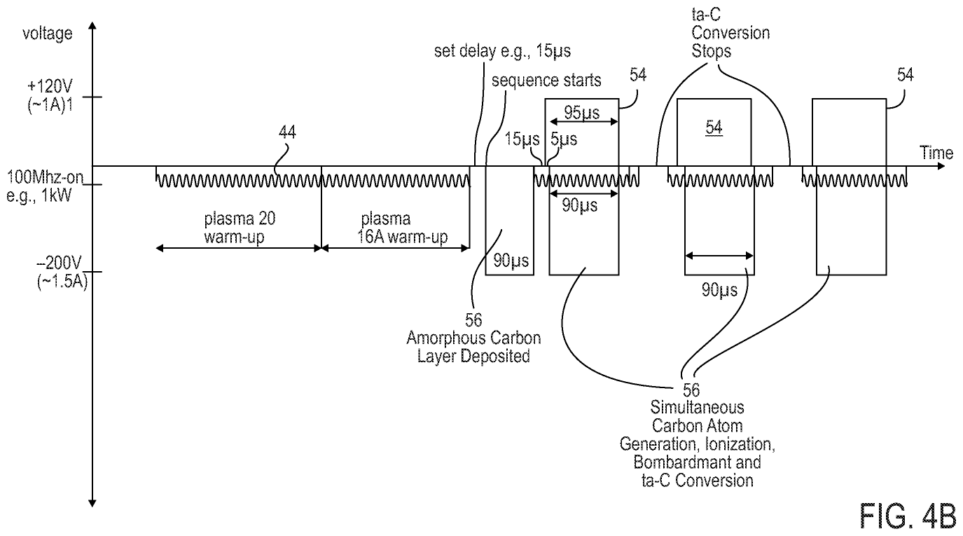

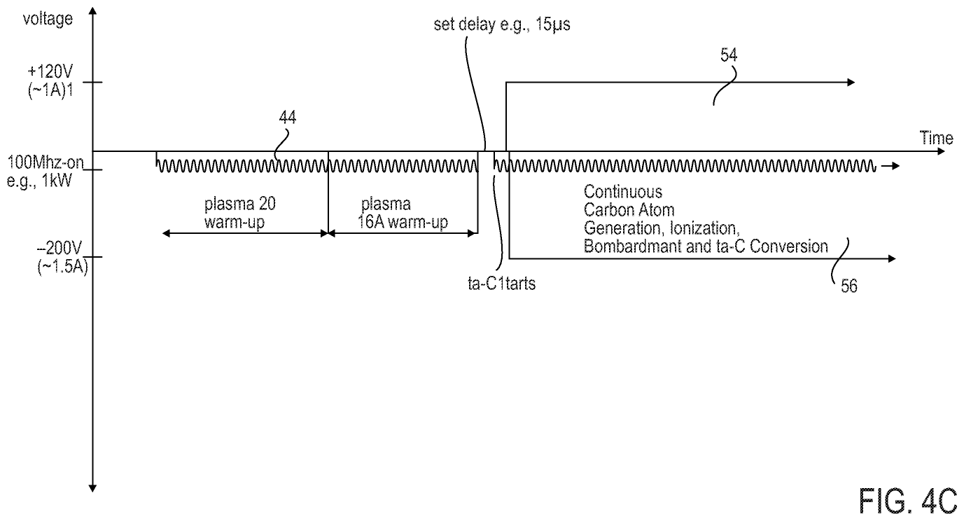

FIG. 4A illustrates the activation of the first plasma and the second plasma in both discrete, non-overlapping, pulses 50 and overlapping pulses 54/56. During pulses 50, the power supply 32 provides a negative voltage of −700 eV to the first plasma source 16. As a result, amorphous carbon atoms of thermal energy are generated. With the overlapping pulses 54 and 56, (a) the RF source 18 is turned on, activating the second plasma, (b) the anode 30 charges the second plasma 20 up to 120 eVolts and (c) the power supply 32 applies a negative voltage of −200 eVolts to first plasma source 16.

When the first plasma 16 is activated, a source of amorphous carbon atoms is created. These carbon atoms rain down and form an amorphous layer on the substrate 26. When the second plasma 20 is activated, a certain percentage of the amorphous carbon atoms are ionized. The ionized carbon ions bombard the substrate, resulting in the spontaneous formation of sp3 bonds by sub-plantation. The carbon atoms that are not ionized continue to deposit on the surface of the substrate 26, adding to the amorphous carbon layer.

The above-described time modulation of the two plasmas defines a two step process for forming to-C:

(1) The deposit of a amorphous carbon layer on the surface of the substrate; and

(2) Conversion of the amorphous carbon layer to ta-C by ion bombardment.

During the ta-C conversion, the bombardment of the positively charged ions creates a build-up of positive charges and a broadening of the Ion Energy Distribution function (IEDf), which may hamper the ta-C conversion. To counteract this build-up, the modulation of the two plasmas is used. By overlapping the first plasma with the second plasma (pulses 54, 56), not only are amorphous carbon atoms generated, but ballistic electrons rush the surface of the substrate 26 as described above with regard to FIG. 1E. The electrons, to some degree, neutralize the positive charge build up across the two-dimensional surface of the substrate 26 caused by ion bombardment. As a result, charge build up can be reduced or otherwise controlled. Similarly, the continuous activation of the two plasmas 16A and 20 can also be used to control the charge buildup on the surface of the substrate 26.

The two-step process differs from Atomic Layer Deposition, since each of the two steps are very short in time, ranging typically less than 100 microseconds and the rate of ion conversion is relatively small (less than 0.01%).

FIG. 4B illustrates the activation of the first plasma and the second plasma in overlapping pulses.

FIG. 4C illustrates the activation of the first plasma and the second plasma continuously.

With both embodiments of FIGS. 4B and 4C, the ta-C conversion occurs substantially the same way as the two step process described above. In other words, when the first plasma 16 is activated, (a) amorphous carbon atoms are generated and deposit on the surface of the substrate 26 and (b) electrons are generated for surface charge control. When the second plasma 20 is activated, a percentage of the carbon atoms are ionized and bombard the substrate, resulting in the to-Ca conversion. In FIG. 4B, the pulses 54 and 56 overlap. In FIG. 4C, the pulses 54 and 56 are continuous.

The above-described process thus provides the ability of selectively and controllably (1) deposited amorphous carbon on a substrate and (2) regulate ion distribution within the processing chamber 12 and (3) control the build-up of surface charges in ways previously not possible. By temporally controlling the activation of the two plasmas, the deposition of the amorphous carbon layer, ion implantation and surface charges can be control spatially in two-dimensions across the surface of the wafer. As a result, the amorphous carbon layer can be transformed into a DLC by the spontaneous formation of sp3 bonds via sub-plantation.

Since the above-described process can be performed in a conventional PECVD tool, it can readily be scaled for industrial production for certain types of substrates, such as semiconductor wafers, flat panel displays and/or photovoltaic devices.

### The ta-C Conversion

During activation of the first plasma 16A, carbon atoms are deposited onto the surface of the substrate 26, forming a very thin amorphous, mono carbon layer of carbon atoms (“C) that is likely just 2-3 atoms in thickness. When the second plasma 20 is activated, the carbon ions (“+C”) of approximately 100 eV has sufficient energy to penetrate below the top amorphous, mono, carbon layer on the surface of the substrate 26. As the carbon ions C+ penetrate, they begin to lose energy due to collisions. In the order of less than a pico-second, the C+ions have lost sufficient energy due to collisions (i.e., likely somewhere between 2 to 5 collisions) to a much lower energy level, likely just a few eVs. At this moment, sp3 bond forms between a carbon atom and a carbon ion C+. In other words, the carbon ion C+ becomes “caged” into a meta-stable state, resulting in formation of sp3 bonds.

The above-conversion process can be illustrated using an example. Consider a situation where (1) approximately −150V is applied to the HCD to generate carbon atoms and (2) a +100V is applied to the anode ring 30. As a result, the boundary driven plasma potential is approximately 100V. At the onset, a 100V plasma 20 sheath is formed and ions start bombarding the surface at an energy of approximately 100 eV. With the simultaneous injection of approximately −150 eV electrons onto the substrate 26, the incident electrons will start to offset the positive charging by the positive C ion bombardment. Now, if the electron flux (with an IEDf that is not mono-energetic but with a distribution, with peak energy around the neighborhood of −150 eV) is higher than that of the positive C ion flux, Vf (the substrate surface floating potential) could actually drifting down towards negative. Now, depending on the exact functional form of the IEDf, the eventual Vf could be, for example, −100V. Since the anode 30 is maintained at +100V, a dynamic equilibrium sheath of 200V results and a continuous +ion energy of approximately 200 eV is hitting the surface of the substrate 26, with an equal number of electron hitting the surface, maintaining the dynamic equilibrium. At this point, the voltage of the anode 30 can be adjusted to +50V to maintain dynamic equilibrium and resetting the boundary driven plasma potential to approximately +50V. This results in a dynamic equilibrium sheath of approximately +150V. Thus, by dynamically adjusting the voltage of the anode, a surface equilibrium of ions and electrons can be maintained and controlled as process conditions change. As a result, the two plasmas 16A and 20 can be continuously and simultaneously activated.

In the alternative embodiment, a surface equilibrium of the substrate 26 can also be achieved by time modulating the two plasmas 16A and 20.

### Pulse Timing

The pulse widths are 54 and 56 and are specified for controlling V_{f} drift-up, which is defined as the drift upward of the surface on the substrate 26 caused by bombardment of the C+ions. In one embodiment, if Vf drift-can be eliminated during the pulses 54 and 56 cycle, then run the “ta-C conversion” can be performed in the continuous mode as illustrated in FIG. 4C. When not operating in the continuous ta-C conversion mode, the pulses 54 and 56 may widely range in width.

The start-time difference between 54 and 56 can also be critical. When 54 pulses on, the potential of the second plasma 20 increases to the artificial potential or boundary-driven potential above the voltage of the anode 30 above the voltage of the anode 30. A safe margin is that it will take approximately one (1) microsecond for to settle at the artificial or boundary-driven potential. Accordingly, by starting the pulse 54 approximately 5 to 15 microseconds prior to pulse 56, more than adequate time is provided for the plasma 20 to stabilize at its artificial or boundary-driven potential. Beyond ten (10) to fifteen (15) microseconds, Vf may begin to drift upward due to ions bombarding the surface of the substrate 26. With this in mind, the time gap between pulses 54 and 56 is preferably around 5 to 10 microseconds and should be no longer than 15 microseconds. Also, by preventing Vf from drifting too much, the energy of the carbon ions C+ is maintained at desirable levels. If Vf drifts too high, then the voltage differential between the plasma 20 at the artificial potential or boundary-driven potential and the substrate 26 decreases, resulting in the carbon ions C+ having less bombardment energy.

### Additional Substrate Surface Charge Control

In certain non-exclusive embodiments, the neutralizing barrier 28 can also be used to control the surface charges on the substrate 26. By making neutralizing barrier 28 from an electron-bearing material, such as graphite plate with holes, available electrons are attracted to the positively charged ions as pass through while bombarding the substrate 26. As a result, the charge of the ions become somewhat neutralized and the energy flux on the surface of the substrate 26 can be reduced. The use of the neutralizing barrier, along with ballistic electrons, can be used together or separately to control the energy flux on the surface of the substrate 26.

### Large Scale Semiconductor Wafer Fabrication

The ability to form DLC layers, such as ta-C in conventional PECVD tools, opens the possibility for large scale, industrial production, of semiconductor wafers.

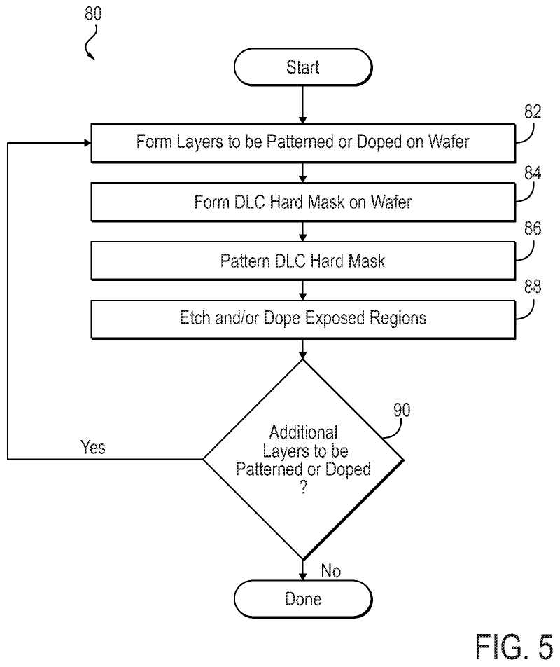

Referring to FIG. 5, a flow diagram 80 for using DLC layers as a hard mask during large scale, industrial, fabrication of semiconductor wafers, is illustrated.

In an initial step 82, any layers that are to be patterned and/or doped on a semiconductor wafer are formed. Such layers may include, but are not limited to, silicon layers, polysilicon layers, metal layers such as aluminum, copper, tungsten, etc., insulating layers, oxide layers, etc.

In step 84, a DLC hard mask layer is formed on the semiconductor wafer as described herein. The DLC layer may be any of the above-recited diamond like materials, including to-C.

In step 86, the DLC hard mask layer is patterned to expose certain regions while covering other regions.

In step 88, the exposed regions on the semiconductor wafer are either etched, doped, or both. The regions of the semiconductor wafer that remained covered by the DLC layer remain protected and are not etched and/or doped.

In decision 90, it is determined if additional layers on the semiconductor wafer nIED to be formed, etched and/or doped. If yes, then the operations 82-88 are repeated. If not, the process is complete, but the wafer will typically undergo other processing steps until fabrication is complete, as is well known in the semiconductor arts.

Again, since the DLC layers can be formed and/or patterned in conventional PECVD tools, the above process can be implemented on a large, industrial scale.

It should be understood that while the embodiments described herein were largely related to deposition tools, this should be by no means construed as limiting. On the contrary, the subject matter as described herein may be used with any type of work piece processing tool, regardless of the type of work piece or how the work piece is processed, including plasma etching tools.

It should be understood that the embodiments provided herein are merely exemplary and should not be construed as limiting in any regard. Although only a few embodiments have been described in detail, it should be appreciated that the present application may be implemented in many other forms without departing from the spirit or scope of the disclosure provided herein. Therefore, the present embodiments should be considered illustrative and not restrictive and is not to be limited to the details given herein, but may be modified within the scope and equivalents of the appended claims.

What is claimed is:

1. A deposition tool, comprising:
a processing chamber;
a substrate holder for holding a substrate within the processing chamber;
a first plasma source configured to generate a first plasma within the processing chamber; and
a second plasma source configured to generate a second plasma within the processing chamber; and
a controller arranged to modulate activation of the first plasma and the second plasma either temporally or spatially with respect to one another within the processing chamber.

2. The deposition tool of claim 1, wherein the controller is arranged to temporally modulate the first plasma and the second plasma by selectively controlling when the first plasma and the second plasma are activated with respect to one another, the first plasma resulting in a generation of atoms of a material that is deposited on the substrate and the second resulting in ions of the material bombarding the substrate.

3. The deposition tool of claim 2, wherein the controller temporally modulates the first plasma and the second plasma in at least one of the following ways:
(a) alternating the activation of the first plasma and the second plasma in discrete, non-overlapping, pulses; or
(b) alternating the activation of the first plasma and the second plasma in partially overlapping, pulses, wherein the temporal modulation occurs during non-overlapping portions of the partially overlapping pulses.

4. The deposition tool of claim 1, wherein the spatial modulation of the first plasma and the second plasma results in the spatial modulation of the atoms generated by the first plasma and the bombardment of the ions resulting from the second plasma across discrete portions of the surface of the substrate.

5. The deposition tool of claim 1, wherein the first plasma is configured to generate low energy atoms that deposit on the substrate while the second plasma is configured to generate high energy ions that bombard the surface of the substrate.

6. The deposition tool of claim 1, wherein the first plasma is generated by one of the following:
(a) a hollow cathode that is at least partially made of a material to be deposited onto the substrate in the processing chamber;
(b) a hollow cathode that is arranged to contain or receive a material that is to be deposited onto the substrate in the processing chamber; or
(c) a magnetron that is arranged to generate particles of a material that is to be deposited onto the substrate in the processing chamber.

7. The deposition tool of claim 1, further comprising a mesh including a plurality of holes positioned adjacent the first plasma source within the processing chamber, the plurality of holes facing the substrate within the processing chamber and allowing atoms generated by the first plasma source to pass from the first plasma to the substrate.

8. The deposition tool of claim 7, wherein the mesh is further arranged to at least partially block electrons present in the first plasma from striking the substrate.

9. The deposition tool of claim 1, wherein the substrate is grounded or biased with respect to the first plasma and the second plasma.

10. The deposition tool of claim 1, further comprising an anode for selectively and dynamically controlling the voltage of the second plasma when activated with respect to the substrate so as to maintain an equilibrium of surface charges on the substrate.

11. The deposition tool of claim 1, further comprising a negative power source for selectively applying a negative voltage to the first plasma when the first plasma is activated with respect to the substrate.

12. The deposition tool of claim 16, wherein the negative voltage is within a range of −100 eV to −200 eV.

13. The deposition tool of claim 1, wherein the second plasma is a Capacitive Coupled Plasma (CCP).

14. The deposition tool of claim 1, wherein the second plasma source includes a Radio Frequency (RF) power source for activating the second plasma.

15. The deposition tool of claim 14, wherein the RF power source is one of the following:
(a) approximately 100 MHz;
(b) approximately 27 MHz;
(c) 13.56 MHz; or
(e) ranging from 400 KHz to 5.0 GHz.

16. The deposition tool of claim 1, wherein the processing chamber is made at least partially of a non-conductive material.

17. The deposition tool of claim 16, wherein the non-conductive material is selected from the group including ceramic, quartz, or other dielectric materials.

18. The deposition tool of claim 1, further comprising an RF loop coupled between the substrate and an RF source used for generating the second plasma, wherein the RF loop effectively defines a ground shield around the processing chamber.

19. The deposition tool of claim 1, further comprising a barrier provided between the second plasma and the substrate, the barrier substantially preventing the second plasma from contacting the substrate.

20. The deposition tool of claim 1, further comprising a neutralizing element, provided between the substrate and the second carbon plasma, the neutralizing element acting to reduce energy flux on the substrate by enabling electrons to combine with ions prior to bombarding the substrate.

21. The deposition tool of claim 1, wherein the material is carbon and the atoms that deposit on the substrate are amorphous carbon atoms that are transformed into an amorphous carbon layer having sp3 bonding.

22. A deposition tool comprising:
a processing chamber;
a substrate holder for holding a substrate within the processing chamber;
a first carbon plasma source for generating a first carbon plasma inside the processing chamber, the first carbon plasma arranged to generate carbon atoms having a low energy that deposit on a surface of the substrate; and
a second plasma configured to ionize the carbon atoms, the carbon ions bombarding the surface of the substrate,
wherein the bombardment of the carbon ions transforming the deposited carbon atoms to a Diamond-Like Carbon (DCL) film on the surface of the substrate.

23. The deposition tool of claim 22, wherein the Diamond-Like Carbon (DCL) film formed on the surface of the substrate occurs via a formation of sp3 bonds that result from the ionized carbon particles bombarding the surface of the substrate.

24. The deposition tool of claim 22, wherein the DCL film consists of the group including hydrogenated amorphous carbon (a-C:H) and hydrogenated tetrahedral amorphous carbon (ta-C:H) and tetrahedral amorphous carbon or “ta-C”

25. The deposition tool of claim 22, wherein the carbon ions are mono-energetic having an energy level with respect to the substrate ranging from 100 eV to 500 eV

26. The deposition tool of claim 22, further comprising a controller arranged to temporally modulate the first carbon plasma and the second plasma within the processing chamber.

27. The deposition tool of claim 26, wherein the controller temporally modulates the first carbon plasma and the second plasma by alternating activation of the first carbon plasma and the second plasma in discrete, non-overlapping, pulses.

28. The deposition tool of claim 26, wherein the controller temporally modulates the first carbon plasma and the second plasma by activation of the first carbon plasma and the second plasma during non-overlapping portions of partially overlapping, pulses respectively.

29. The deposition tool of claim 26, wherein the controller spatially modulates the first carbon plasma and the second plasma activating the first carbon plasma and the second plasma continuously as the DCL film is formed on the surface of the substrate.

30. The deposition tool of claim 26, wherein the controller modulates the first carbon plasma and the second plasma to maintain and control an equilibrium of surface charges on the surface of the substrate.

31. The deposition tool of claim 30, wherein the controller controls the surface charges on the surface of the substrate by controlling an energy of electrons that strike the surface of the substrate, the electrons offset positive charges collecting on the surface of the wafer due to the bombardment of the carbon ions.

32. The deposition tool of claim 31, wherein the controller causes the electrons to be generated by activating the first plasma.

33. The deposition tool of claim 22, wherein the spatial modulation of the first plasma and the second plasma results in the spatial modulation of the carbon atoms and the bombardment of the carbon ions across discrete locations on a surface of the substrate respectively.

34. The deposition tool of claim 22, further comprising a neutralizing element, provided between the substrate and the second plasma, the neutralizing element neutralizing a charge of the carbon ions prior to bombarding the surface of the substrate.

35. The deposition tool of claim 34, wherein the neutralizing element is a graphite plate having a plurality of holes that enable the carbon ions to attract electrons as the carbon ions pass through the neutralizing element.

36. The deposition tool of claim 22, further comprising a barrier element arranged to prevent the second plasma from contacting the substrate.

37. The deposition tool of claim 22, wherein the substrate holder is configured to maintain the temperature of the substrate at or below approximately 300° C.

38. The deposition tool of claim 22, wherein the first carbon source is hollow cathode.

39. The deposition tool of claim 38, wherein the hollow cathode is made from graphite.

40. The deposition tool of claim 38, wherein the hollow cathode includes a plurality of cells and a carbon particle generating material is arranged to be inserted into or contained within the plurality of cells.

41. The deposition tool of claim 22, wherein the first carbon source is a magnetron.

42. The deposition tool of claim 22, wherein the first carbon plasma is generated by the first carbon plasma source by:
igniting carbon in a hollow chamber included in the first carbon plasma source by supplying an ignition gas into the hollow chamber;
after the carbon is ignited, weaning or stopping the supply of the ignition gas into the hollow chamber;
wherein after the supply of the ignition gas is weaned or stopped, the first carbon plasma contains substantially only carbon.

43. The deposition tool of claim 22, wherein a negative voltage is applied to the first plasma source when the first carbon plasma is generated, the negative voltage within a range of −100 eV to −200 eV.

44. The deposition tool of claim 22, wherein the second plasma is a Capacitive Coupled Plasma (CCP).

45. The deposition tool of claim 22, wherein the second plasma is activated by a Radio Frequency (RF) power source, wherein the RF power source is one of the following:
(a) approximately 100 MHz;
(b) approximately 27 MHz;
(c) 13.56 MHz; or
(e) ranging from 400 KHz to 5.0 GHz.

46. The deposition tool of claim 22, further comprising an anode for selectively controlling the voltage of the second plasma.

47. The deposition tool of claim 22, wherein the substrate is maintained at ground or is biased with respect to the first carbon plasma and the second plasma.
